(19) United States
(12) Patent Application Publication
(10) Pub. No.: US 2009/0159916 A1
(43) Pub. Date: Jun. 25, 2009

(54) LIGHT SOURCE WITH REFLECTIVE PATTERN STRUCTURE

(76) Inventors: CHIEN-GHUNG FU, HSINCHU CITY (TW); CHENG-HUAN CHEN, HSINCHU CITY (TW); HAO-CHUNG KUO, HSINCHU CITY (TW)

Correspondence Address: Muncy, Geissler, Olds & Lowe, PLLC, P.O. BOX 1364, FAIRFAX, VA, 22038-1364, US

(21) Appl. No.: 12/336,336

(22) Filed: Dec. 16, 2008

(30) Foreign Application Priority Data
Dec. 20, 2007 (TW) 096149038

(51) Int. Cl. H01L 33/00

(52) U.S. Cl. 257/98; 257/E33.067

(57) ABSTRACT

A light source includes a substrate and a light-emitting unit. The substrate has a pattern structure, which includes a plurality of concave-convex structures. The light-emitting unit is formed on the pattern structure, and has a backlight surface connected to the pattern structure and a light outputting surface disposed opposite the backlight surface. The pattern structure reflects light, which is outputted from the light-emitting unit in a direction toward the backlight surface, to the light outputting surface.

This application claims priority of No. 096149038 filed in Taiwan R.O.C. on Dec. 20, 2007 under 35 USC 119, the entire content of which is hereby incorporated by reference.

### BACKGROUND OF THE INVENTION

1. Field of Invention

The invention relates to a light source, and more particularly to a light source with a reflective pattern structure, which may be a nanometer-scaled pattern structure or a composite pattern structure composed of the nanometer-scaled pattern structure and a micron-scaled pattern structure.

2. Related Art

Light sources, which become more and more popular, include a light-emitting diode and a laser diode. The light-emitting diode is a cold lighting element for releasing the energy, which is generated when electrons and holes in the semiconductor material are combined together, in the form of light. Different light rays with different wavelengths may be outputted according to different properties of the used materials. The outputted light rays cover the visible light rays and the invisible light rays, such as infrared light or ultra-violet light. Compared with the conventional light bulb or lamp, the light-emitting diode advantageously has the power-saving property, the vibration resistant property, the long lifetime and the high flickering speed, so the light-emitting diode has become the indispensable element in the daily life. On the other hand, the laser diode is mainly adapted to the optical communication and optical storage devices.

The basic light-emitting diode includes a substrate, a buffer layer formed on the substrate, an N-type semiconductor layer formed on the buffer layer, an active layer partially covering the N-type semiconductor layer, a P-type semiconductor layer formed on the active layer, and two contact electrode layers respectively formed on the two semiconductor layers.

The active layer of the conventional light-emitting diode has the high dislocation density so that the internal quantum efficiency of the light-emitting diode is decreased, the light-emitting luminance thereof is decreased, the heat is generated, the temperature of the light-emitting diode is increased and the light-emitting efficiency is thus influenced. In addition, the light rays outputted from the active layer travel toward many directions, and the light rays outputted toward the backlight surface are absorbed by the substrate so that the light-emitting luminance is decreased.

FIG. 6 is a schematic illustration showing a conventional package of a light source. As shown in FIG. 6, a light source 100 is packaged in a reflective cup 110. For the reason mentioned hereinabove, some light rays are emitted from a light outputting surface 102 to a backlight surface 104. Thus, the reflective cup 110 has to be provided to reflect some light rays upward to enhance the light-emitting luminance. The reflective cup 110 is disadvantageous to the decrease of the cost and the reduction of size.

Thus, it is an important subject of the invention to provide a light source with the light reflecting function, the reduced dislocation density, the enhanced light-emitting efficiency and the reduced temperature rise.

### SUMMARY OF THE INVENTION

It is therefore an object of the invention to provide a light source, which has a reflective pattern structure, the reduced dislocation density, the enhanced light-emitting efficiency and the reduced temperature rise, and does not need a reflective cup.

To achieve the above-identified object, the invention provides a light source, which includes a substrate and a light-emitting unit. The substrate has a pattern structure, which includes a plurality of concave-convex structures. The light-emitting unit is formed on the pattern structure, and has a backlight surface connected to the pattern structure, and a light outputting surface disposed opposite the backlight surface. The pattern structure reflects light, which is outputted from the light-emitting unit in a direction toward the backlight surface, to the light outputting surface.

Further scope of the applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1 is a schematic illustration showing a light source according to a preferred embodiment of the invention.

FIGS. 2 to 4 show several examples of pattern structures of the light sources according to the preferred embodiment of the invention.

FIGS. 5A to 5E show some structures corresponding to some steps of the method of manufacturing the light source according to the preferred embodiment of the invention.

FIG. 6 is a schematic illustration showing a conventional package of a light source.

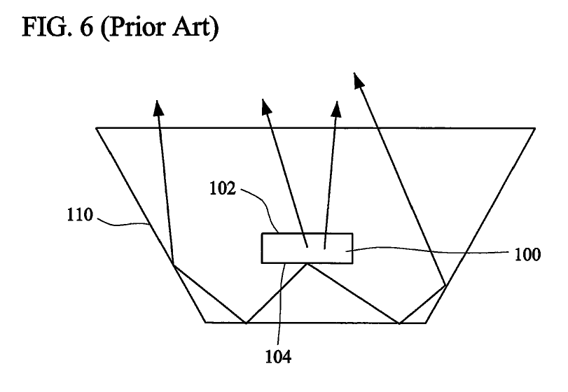

### DETAILED DESCRIPTION OF THE INVENTION

The present invention will be apparent from the following detailed description, which proceeds with reference to the accompanying drawings, wherein the same references relate to the same elements.

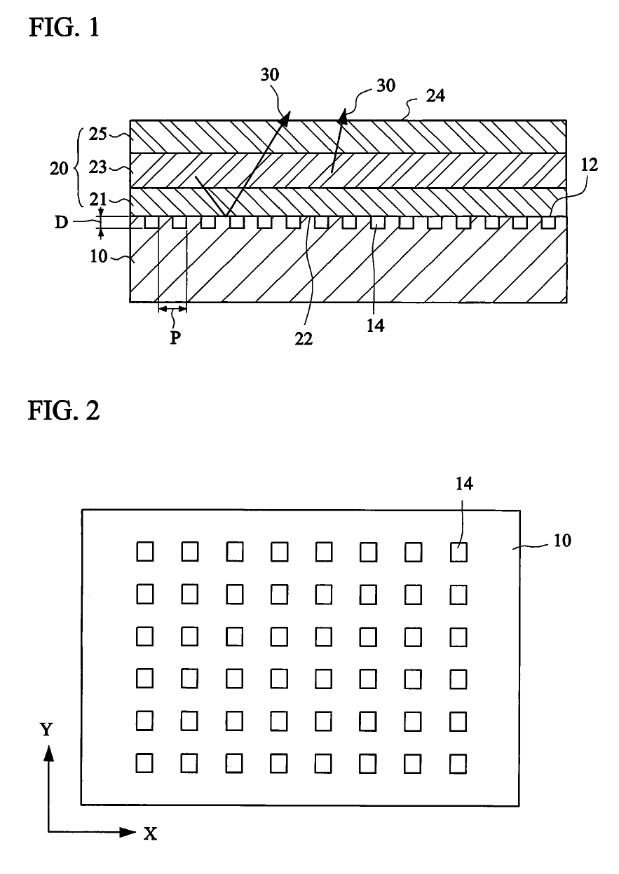

FIG. 1 is a schematic illustration showing a light source according to a preferred embodiment of the invention. As shown in FIG. 1, the light source of this embodiment may be a light-emitting diode device or a laser diode device, and includes a substrate 10 and a light-emitting unit 20. The light-emitting diode device may be a diode for outputting red, green or blue light, or the light with other wavelengths.

The material of the substrate may be selected from the group consisting of silicon, silicon carbide, magnesium oxide, arsenide (e.g., gallium arsenide (GaAs), indium gallium aluminum phosphide (InGaAlP), aluminum gallium arsenide (AlGaAs)), phosphide (e.g., gallium phosphide (GaP), gallium phosphide nitride (GaPN), gallium arsenide phosphide (GaAsP), indium aluminum gallium phosphide (InAlGaP)), zinc oxide and sapphire. The substrate 10 has a pattern structure 12, which may be a nanometer-scaled pattern structure or a composite pattern structure composed of the nanometer-scaled pattern structure and a micron-scaled pattern structure. The light-emitting unit 20 is formed on the pattern structure 12. The light-emitting unit 20 has a backlight surface 22 connected to the pattern structure 12, and a light outputting surface 24 disposed opposite the backlight surface 22. The pattern structure 12 reflects light 30, which is outputted from the light-emitting unit 20 in a direction toward the backlight surface 22, to the light outputting surface 24.

In this embodiment, the light-emitting unit 20 includes a first-type semiconductor layer 21, an active layer 23 and a second-type semiconductor layer 25. The first-type semiconductor layer 21 is in direct contact with the pattern structure 12. The active layer 23 disposed on the first-type semiconductor layer 21 outputs the light 30. The second-type semiconductor layer 25 is disposed on the active layer 23. The light-emitting unit 20 also has two electrodes (not shown). After the electrodes are powered, the active layer 23 may be excited to output the light 30.

The first-type semiconductor layer 21 may be a P-type or an N-type semiconductor layer, while the second-type semiconductor layer 25 may be an N-type or a P-type semiconductor layer. The first-type semiconductor layer 21 may be, for example, a gallium nitride (GaN) layer, an aluminum-indium-gallium-nitride (AlInGaN) layer, an aluminum gallium nitride (AlGaN) layer or an aluminum indium nitride (AlInN) in direct contact with the pattern structure 12.

In this embodiment, the pattern structure 12 includes a plurality of concave-convex structures 14. The concave-convex structure 14 may have a rectangular shape, a square shape, a circular shape, an elliptic shape, a strip shape or any other shape. The concave-convex structure 14 may be non-periodically arranged in a straight line, or be periodically arranged in a straight line. Alternatively, the concave-convex structure 14 may be non-periodically arranged in a two-dimensional array, or be periodically arranged in a two-dimensional array. The so-called non-periodical arrangement represents, without limitation to, that the concave-convex structures 14 have different pitches or different duty cycles.

The concave-convex structure 14 has a nanometer-scaled size. For example, a pitch P of the concave-convex structure 14 is smaller than one micron. A depth D of each concave-convex structure 14 ranges between several tens of nanometers and several microns. The pattern structure 12 can effectively reduce the dislocation density of the first-type semiconductor layer (e.g., the GaN layer) 21 so that the special optical property can be obtained. That is, the pattern structure 12 may be configured to be equivalent to a double refraction film according to the effective medium theory so that the reflecting function is obtained. For example, the light outputted from the visible light light-emitting diode has the wavelength ranging between 350 and 750 nm. The pitch of the concave-convex structures 14 may be configured to be smaller than or equal to one half of the wavelength of the light 30 so that the effect of reflecting the light 30 can be generated. At this time, the light 30 cannot enter the substrate 10 so that the light-emitting luminance can be enhanced.

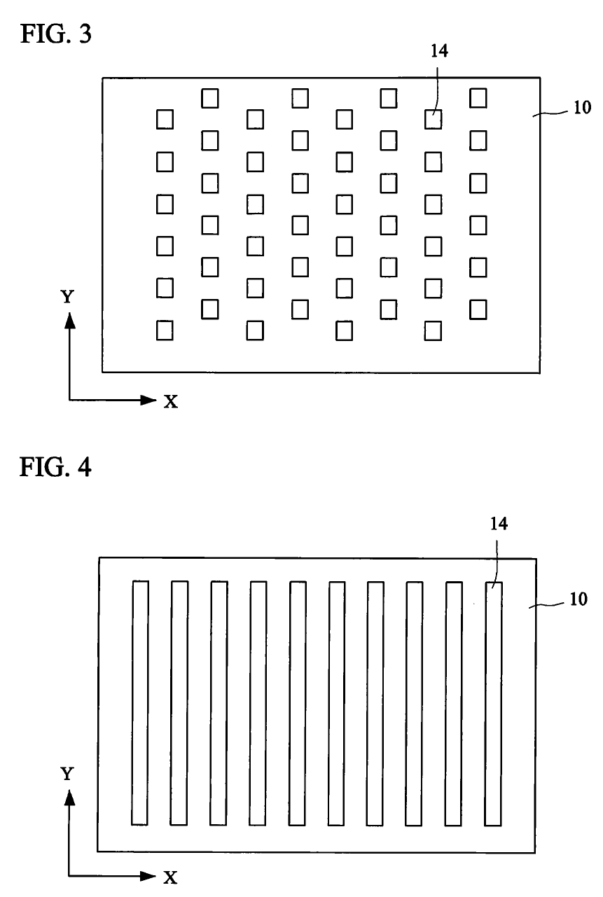

FIGS. 2 to 4 show several examples of the pattern structures of the light sources according to the preferred embodiment of the invention. As shown in FIGS. 2 and 3, the concave-convex structures 14 may be arranged in a two-dimensional array, which has an X direction and a Y direction, and the concave-convex structures 14 have the same pitch and/or the same duty cycle in the X direction and the Y direction. The duty cycle represents the ratio of the concave portion to the convex portion. In other embodiments, the concave-convex structures 14 have different pitches and/or different duty cycles in the X direction and the Y direction. Alternatively, these concave-convex structures 14 may be periodically arranged in a one-dimensional array, as shown in FIG. 4, or may be non-periodically arranged in a one-dimensional array.

Adjusting the pitches, duty cycles and/or depths of the concave-convex structures 14 of FIGS. 1 to 4 in the X direction and the Y direction can arrange the concave-convex structures 14 in the two-dimensional array (or the one-dimensional array in FIG. 4) to have the function of polarized selective reflection so that the light 30 with differently polarized directions can be selectively reflected and the concave-convex structures 14 are equivalent to a specific light filter.

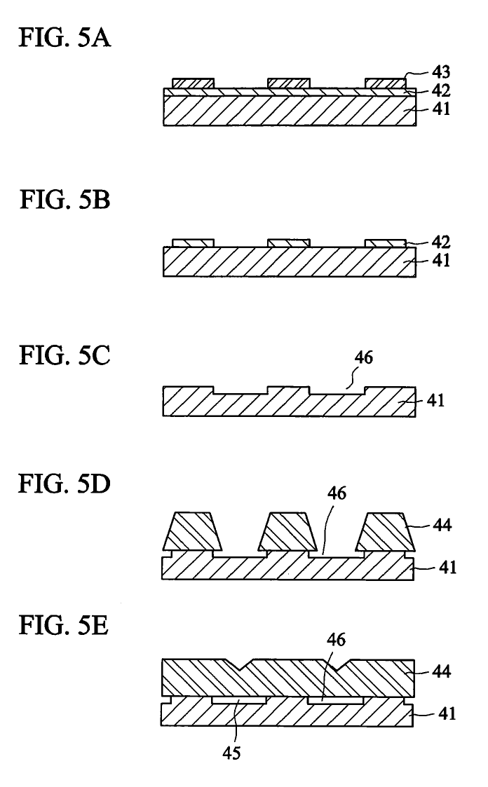

FIGS. 5A to 5E show some structures corresponding to some steps of the method of manufacturing the light source according to the preferred embodiment of the invention. First, an auxiliary layer (silicon dioxide SiO₂ or silicon nitride SiNₓ) 42 is formed on a sapphire substrate 41. Next, a photoresist pattern layer 43 is formed on the auxiliary layer 42 according to the photo-lithography technology, as shown in FIG. 5A. Next, the auxiliary layer 42 is patterned by way of etching, and the photoresist pattern layer 43 is removed, as shown in FIG. 5B. Then, the sapphire substrate 41 is etched, with the patterned auxiliary layer 42 serving as a mask, to form several cavities 46, and the auxiliary layer 42 is removed, as shown in FIG. 5C. Next, a nitride semiconductor layer (e.g., the GaN layer) 44 is formed on the sapphire substrate 41 according to the metal organic chemical vapor deposition (MOCVD) technology. The nitride semiconductor layer 44 may be controlled to deposit mainly along a specific direction, as shown in FIG. 5D. Finally, the nitride semiconductor layer 44 seals the cavities of the sapphire substrate 41 along the horizontal direction to form concave-convex structures 45, as shown in FIG. 5E. The concave-convex structures 45 correspond to the concave-convex structures 14 of FIG. 1.

The light source according to the invention has the output power, which can be effectively enhanced. The main reason is that the pattern structure can provide the function of reflecting the light, and can effectively reduce the dislocations in the nitride semiconductor layer and the sapphire substrate to enhance the light-emitting efficiency significantly. In addition, the pattern structure can reflect the light, so the perfect effect of outputting light from only one single light outputting surface can be obtained. Thus, the light source of the invention can be packaged without the conventional reflective cup. On the other hand, the amount of the light outputted from the active layer and absorbed by the sapphire substrate can be reduced and the total light-emitting efficiency can be enhanced. Furthermore, because the light-emitting surface is only the upper light outputting surface, the light-emitting area is only equal to one half that of the prior art, and the etendue is only equal to that of the prior art. So, it is advantageous to the enhancement of the collection efficiency in the illumination application (e.g., the display light, the vehicle headlamp, the flashlight and the task lighting) with the smaller light receiving area. In addition, the pattern structure can improve the reflection of the normal light and thus change the output light distribution. Thus, the overall light shape can be well orientated. That is, the half angle can be decreased so that the light-emitting area can be reduced.

While the invention has been described by way of examples and in terms of preferred embodiments, it is to be understood that the invention is not limited thereto. To the contrary, it is intended to cover various modifications. Therefore, the scope of the appended claims should be accorded the broadest interpretation so as to encompass all such modifications.

What is claimed is:

1. A light source with a reflective pattern structure, the light source comprising:
a substrate having a pattern structure, which comprises a plurality of concave-convex structures; and
a light-emitting unit, which is formed on the pattern structure and has a backlight surface connected to the pattern structure, and a light outputting surface disposed opposite the backlight surface, wherein the pattern structure reflects light, which is outputted from the light-emitting unit in a direction toward the backlight surface, to the light outputting surface.

2. The light source according to claim 1, wherein a pitch of the concave-convex structures is smaller than or equal to one half of a wavelength of the light.

3. The light source according to claim 1, wherein the concave-convex structures are arranged in a two-dimensional array to have a function of polarized selective reflection for selectively reflecting the light with differently polarized directions.

4. The light source according to claim 1, wherein the concave-convex structures are arranged in a two-dimensional array, which has an X direction and a Y direction, and the concave-convex structures have different pitches in the X direction and the Y direction.

5. The light source according to claim 1, wherein the concave-convex structures are arranged in a two-dimensional array, which has an X direction and a Y direction, and the concave-convex structures have different duty cycles in the X direction and the Y direction.

6. The light source according to claim 1, wherein the concave-convex structures are arranged in a two-dimensional array, which has an X direction and a Y direction, and the concave-convex structures have different pitches and different duty cycles in the X direction and the Y direction.

7. The light source according to claim 1, wherein the concave-convex structures are arranged in a one-dimensional array to have a function of polarized selective reflection for selectively reflecting the light with differently polarized directions.

8. The light source according to claim 1, wherein a pitch of the concave-convex structures is smaller than one micron.

9. The light source according to claim 1, wherein a depth of each of the concave-convex structures ranges between several tens of nanometers and several microns.

10. The light source according to claim 1, wherein a material of the substrate is selected from the group consisting of silicon, silicon carbide, magnesium oxide, arsenide, phosphide, zinc oxide and sapphire.

11. The light source according to claim 1, wherein the light-emitting unit comprises a nitride semiconductor layer in direct contact with the pattern structure.

12. The light source according to claim 1, wherein the concave-convex structures are non-periodically arranged in a two-dimensional array.

13. The light source according to claim 1, wherein the concave-convex structures are periodically arranged in a two-dimensional array.

14. The light source according to claim 1, wherein the concave-convex structures are non-periodically arranged in a one-dimensional array.

15. The light source according to claim 1, wherein the concave-convex structures are periodically arranged in a one-dimensional array.

16. The light source according to claim 1 being a light-emitting diode device or a laser diode device.

17. The light source according to claim 1, wherein the light-emitting unit comprises:
a first-type semiconductor layer in direct contact with the pattern structure;
an active layer, disposed on the first-type semiconductor layer, for outputting the light; and
a second-type semiconductor layer disposed on the active layer.

18. The light source according to claim 1, wherein the pattern structure is a nanometer-scaled pattern structure or a composite pattern structure composed of the nanometer-scaled pattern structure and a micron-scaled pattern structure.

19. The light source according to claim 1, wherein each of the concave-convex structures has a rectangular shape, a square shape, a circular shape, an elliptic shape or a strip shape.
